(19) United States
(12) Patent Application Publication
(10) Pub. No.: US 2024/0258984 A1
(43) Pub. Date: Aug. 1, 2024

(54) ELECTRICAL AND ELECTRONIC APPARATUS

(71) Applicant: Mitsubishi Electric Corporation, Tokyo (JP)

(72) Inventor: Kenji HIROSE, Tokyo (JP)

(73) Assignee: Mitsubishi Electric Corporation, Tokyo (JP)

(21) Appl. No.: 18/632,466

(22) Filed: Apr. 11, 2024

Related U.S. Application Data
(63) Continuation of application No. PCT/JP2021/046901, filed on Dec. 20, 2021.

(51) Int. Cl. H03H 7/09; H03H 7/01; H05K 9/00

(52) U.S. Cl. CPC H03H 7/09; H03H 7/0115; H05K 9/0007

(57) ABSTRACT

Disclosed is electrical and electronic apparatus that is configured in such a way as to include: a case which is a conductor; a terminal mounted to the case; a conductor wire whose one end is connected to the terminal and whose other end is connected to a circuit accommodated in the case; a capacitor whose one end is connected to the conductor wire; a case connection portion whose one end is connected to the other end of the capacitor and whose other end is connected to the case; and a wall whose peripheral part is in space enclosed by the case, the conductor wire, and the case connection portion, and is connected to the case in a state in which the wall is not in contact with the conductor wire.

### CROSS REFERENCE TO RELATED APPLICATIONS

This application is a Continuation of PCT International Application No. PCT/JP2021/046901, filed on Dec. 20, 2021, all of which is hereby expressly incorporated by reference into the present application.

### TECHNICAL FIELD

The present disclosure relates to an electrical and electronic apparatus.

### BACKGROUND ART

There is an electrical and electronic apparatus which includes a filter circuit to reduce the leakage of electromagnetic noise to outside the electrical and electronic apparatus (see Patent Literature 1). The filter circuit includes: a conductor wire whose one end is connected to a terminal mounted to a metal case of the electrical and electronic apparatus and whose other end is connected to a circuit (referred to as an “internal circuit” hereinafter) other than the filter circuit, the internal circuit being accommodated in the metal case; and a capacitor whose one end is connected to the conductor wire and whose other end is connected to the metal case.

Noise generated from the internal circuit may be superimposed, as a noise current, onto the conductor wire. The capacitor acts in such a way as to make it easy for the noise current superimposed onto the conductor wire to flow through the metal case. Because the filter circuit thus includes the capacitor, the electric potential difference between the conductor wire and the metal case becomes small. The electric potential difference between the conductor wire and the metal case corresponds to a noise voltage generated between the metal case and the terminal. As a result, the amount of leakage of electromagnetic noise from the terminal to outside the electrical and electronic apparatus, the electromagnetic noise being caused by the noise voltage, decreases.

However, when a noise magnetic field which is a magnetic field caused by the noise generated from the internal circuit interlinks with space enclosed by the conductor wire and the metal case, an induced current flows through loop-shaped path according to the law of electromagnetic induction, and an induced voltage is generated between the metal case and the terminal. The loop-shaped path is a path connecting the conductor wire, the capacitor, the metal case, the terminal, and the conductor wire.

In the electrical and electronic apparatus, the whole of the filter circuit is enclosed by a shielding case in order to reduce the electromagnetic noise caused by the induced voltage and leaked out from the terminal.

### CITATION LIST

### Patent Literature

Patent Literature 1: JP 2017-212496 A

### SUMMARY OF INVENTION

### Technical Problem

A problem with the electrical and electronic apparatus disclosed in Patent Literature 1 is that a shielding case having a size which makes it possible to enclose the whole of the filter circuit should be disposed.

The present disclosure is made in order to solve the above-mentioned problem, and it is therefore an object of the present disclosure to provide an electrical and electronic apparatus that can reduce electromagnetic noise leaked out from a terminal without having to dispose a shielding case having a size which makes it possible to enclose the whole of a filter circuit, and in which a placement space of its wall is smaller than a case placement space.

### Solution to Problem

An electrical and electronic apparatus according to the present disclosure includes: a case which is a conductor; a terminal mounted to the case; at least one conductor wire whose one end is connected to the terminal and whose other end is connected to a circuit accommodated in the case; at least one capacitor whose one end is connected to the at least one conductor wire; a case connection portion whose one end is connected to another end of the at least one capacitor and whose other end is connected to the case; and a wall whose peripheral part is connected to the case, the wall being positioned in space enclosed by the case, the at least one conductor wire, and the case connection portion, and being in a state in which the wall is not in contact with the at least one conductor wire. The wall is placed in such a way that a side opposite to another side connected to the wall, out of sides which the case has, extends along the at least one conductor wire.

### Advantageous Effects of Invention

According to the present disclosure, electromagnetic noise leaked out from the terminal can be reduced without having to dispose a shielding case having a size which makes it possible to enclose the whole of a filter circuit, and the placement space of the wall is smaller than the case placement space.

### BRIEF DESCRIPTION OF DRAWINGS

FIG. 1A is an explanatory drawing when a cross section A-A′ of an electrical and electronic apparatus shown in FIGS. 1A and 1B is viewed from a Y direction, and FIG. 1B is an explanatory drawing when the inside of a case 1 of the electrical and electronic apparatus is viewed from a Z direction;

FIG. 2A is an explanatory drawing showing an induced voltage V₁ and Loop in the case where a wall 6 is not disposed, and FIG. 2B is an explanatory drawing showing an induced voltage V₂ and Loop: when a wall 6 is disposed;

FIG. 3A is an explanatory drawing when a cross section A-A′ of an electrical and electronic apparatus shown in FIGS. 3A and 3B is viewed from a Y direction, and FIG. 3B is an explanatory drawing when the inside of a case 1 of the electrical and electronic apparatus is viewed from a Z direction;

FIG. 4A is an explanatory drawing when a cross section A-A′ of an electrical and electronic apparatus shown in FIGS. 4A and 4B is viewed from a Y direction, and FIG. 4B is an explanatory drawing when the inside of a case 1 of the electrical and electronic apparatus is viewed from a Z direction;

FIG. 5A is an explanatory drawing when a cross section A-A′ of an electrical and electronic apparatus shown in FIGS. 5A and 5B is viewed from a Y direction, and FIG. 5B is an explanatory drawing when the inside of a case 1 of the electrical and electronic apparatus is viewed from a Z direction; and

FIG. 6A is an explanatory drawing when a cross section A-A′ of an electrical and electronic apparatus shown in FIGS. 6A and 6B is viewed from a Y direction, and FIG. 6B is an explanatory drawing when the inside of a case 1 of the electrical and electronic apparatus is viewed from a Z direction.

### DESCRIPTION OF EMBODIMENTS

Hereinafter, in order to explain the present disclosure in greater detail, embodiments of the present disclosure will be explained with reference to the accompanying drawings.

### Embodiment 1

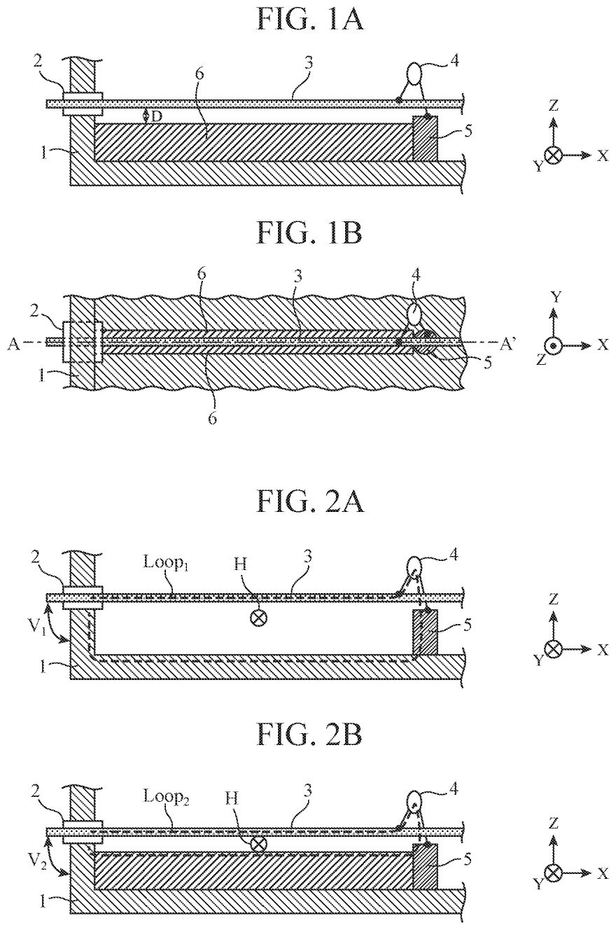

FIGS. 1A and 1B each is a configuration diagram showing portion of an electrical and a power supply terminal electronic apparatus according to Embodiment 1.

FIG. 1A is an explanatory drawing when a cross section A-A′ of the electrical and electronic apparatus shown in FIGS. 1A and 1B is viewed from a Y direction.

FIG. 1B is an explanatory drawing when the inside of a case 1 of the electrical and electronic apparatus is viewed from a Z direction.

The electrical and electronic apparatus shown in FIGS. 1A and 1B includes a filter circuit and a circuit needed for the operation of the electrical and electronic apparatus. The filter circuit includes the case 1, a terminal 2, a conductor wire 3, a capacitor 4, a case connection portion 5, and a wall 6. The circuit needed for the operation of the electrical and electronic apparatus is the circuitry (referred to as the “internal circuit” hereinafter) other than the filter circuit, the internal circuit being accommodated in the case 1.

In FIGS. 1A and 1B, X, Y, and Z show a coordinate system showing three-dimensional space in which the electrical and electronic apparatus is placed.

The case 1 is implemented by a conductor such as a metal.

In the electrical and electronic apparatus shown in FIGS. 1A and 1B, the case 1 covers the power supply terminal portion of the electrical and electronic apparatus. Although not illustrated in FIGS. 1A and 1B, the case 1 covers not only the power supply terminal portion of the electrical and electronic apparatus, but also the internal circuit.

The terminal 2 is mounted to the case 1 in order to electrically connect the conductor wire 3 and an external device or the like outside the electrical and electronic apparatus.

The terminal 2 is a connector including a conductor such as a metal, and an insulator such as resin. The conductor included in the terminal 2 is connected to one end of the conductor wire 3. The insulator included in the terminal 2 is mounted to the case 1 so that the conductor included in the terminal 2 is not in contact with the case 1.

One end of the conductor wire 3 is connected to the conductor included in the terminal 2, and the other end of the conductor wire 3 is connected to the internal circuit.

The conductor wire 3 is a conductor such as a metal. The conductor wire 3 is placed inside the case 1 and parallel to an X-Y plane.

In the electrical and electronic apparatus shown in FIGS. 1A and 1B, the conductor wire 3 is placed parallel to the X-Y plane. However, this is only an example, and the conductor wire 3 may be placed inside the case 1 and not parallel to the X-Y plane.

Further, in the electrical and electronic apparatus shown in FIGS. 1A and 1B, the longitudinal direction of the conductor wire 3 is parallel to the X axis, and the conductor wire 3 is a linear line. However, this is only an example, and the conductor wire 3 may be bent in the middle and a part of the conductor wire 3 may extend in a direction not parallel to the X axis, for example.

The capacitor 4 is a two-terminal capacitor part with a lead wire.

A first terminal which is one end of the capacitor 4 is connected to the conductor wire 3. A second terminal which is the other end of the capacitor 4 is connected to one end of the case connection portion 5.

The case connection portion 5 is a pillar-shaped structure which is constituted by a conductor such as a metal.

One end of the case connection portion 5 is connected to the second terminal of the capacitor 4. The other end of the case connection portion 5 is connected to the case 1.

In the electrical and electronic apparatus shown in FIGS. 1A and 1B, the longitudinal direction of the case connection portion 5 is parallel to the Z axis. The one end of the case connection portion 5 should just be connected to the second terminal of the capacitor 4 and the other end of the case connection portion 5 should just be connected to the case 1, and the longitudinal direction of the case connection portion 5 may be inclined with respect to the Z axis.

The wall 6 is a surface-shaped structure which is constituted by a conductor such as a metal.

The wall 6 has a peripheral part which is in space enclosed by the case 1, the conductor wire 3, and the case connection portion 5, and which is connected to the case 1 in a state in which the wall 6 is not in contact with the conductor wire 3.

In the electrical and electronic apparatus shown in FIGS. 1A and 1B, the wall 6 has a rectangular shape in a Z-X plane, and the wall 6 has four sides. One of the four sides which is connected to the case 1 (the lower side in FIG. 1A) is the peripheral part of the wall 6, the peripheral part being connected to the case 1.

In the electrical and electronic apparatus shown in FIGS. 1A and 1B, the wall 6 is placed in such a way that the side (the upper side in FIG. 1A) opposite to the lower side in FIG. 1A, out of the four sides, extends along the conductor wire 3.

The distance D between the conductor wire 3 and the upper side in FIG. 1A is longer than the insulation distance decided by a safety standard or the like, in order to prevent electrical shorts or electric discharges in the space.

In the electrical and electronic apparatus shown in FIGS. 1A and 1B, the shape in the Z-X plane of the wall 6 is a rectangle. However, the shape in the Z-X plane of the wall 6 is not limited to a rectangle. Therefore, the shape in the Z-X plane of the wall 6 may be a semicircle, an ellipse, or a polygon other than a rectangle, for example.

For example, in the case where the shape in the Z-X plane of the wall 6 is a semicircle, and the straight line portion of the semicircle is connected to the case 1, the peripheral part of the wall 6, the peripheral part being connected to the case 1, is the straight line portion of the semicircle. Instead, in the case where a point in the curved portion of the semicircle is connected to the case 1, the peripheral part of the wall 6, the peripheral part being connected to the case 1, is the point in the curved portion.

In the electrical and electronic apparatus shown in FIGS. 1A and 1B, the peripheral part of the wall 6 should just be mechanically connected to the case 1, and the peripheral part of the wall 6 may be electrically connected to the case 1 or may not be electrically connected to the case 1.

Next, the operation of the electrical and electronic apparatus shown in FIGS. 1A and 1B will be explained.

Hereinafter, for the sake of convenience in explanation, it is assumed that a positive side terminal of a DC power supply (not illustrated) outside the electrical and electronic apparatus shown in FIGS. 1A and 1B is connected, via a cable or the like, to the conductor included in the terminal 2, and a negative side terminal of the DC power supply is connected, via a cable or the like, to the case 1.

Power supplied from the DC power supply is supplied, via the conductor included in the terminal 2 and the conductor wire 3, to the internal circuit. When the internal circuit operates, noise may be generated from the internal circuit.

Noise generated from the internal circuit is superimposed, as a noise voltage or a noise current, onto the conductor wire 3.

The capacitor 4 acts in such a way that the noise current superimposed onto the conductor wire 3 easily flows through the case 1. Because the electrical and electronic apparatus thus includes the capacitor 4, the electric potential difference between the case 1 and the conductor wire 3 becomes small. The electric potential difference between the case 1 and the conductor wire 3 corresponds to the noise voltage generated between the case 1 and the terminal 2. As a result, the amount of leakage of electromagnetic noise from the terminal 2 to the outside, the electromagnetic noise being caused by the noise voltage, decreases.

FIGS. 2A and 2B each is an explanatory drawing showing the action of the wall 6 disposed in the electrical and electronic apparatus.

FIG. 2A shows an induced voltage V₁ and Loop₁ in the case where the wall 6 is not disposed.

FIG. 2B shows an induced voltage V₂ and Loop₂ in the case where the wall 6 is disposed.

In the figure, H denotes a magnetic field (referred to as the “noise magnetic field” hereinafter) caused by the noise generated from the internal circuit.

Each of the induced voltages V₁ and V₂ is a voltage component induced by the noise magnetic field H, the voltage component being contained in the noise voltage generated between the case 1 and the terminal 2.

Each of the loops: Loop₁ and Loop₂ is a path through which an induced current generated when, for example, the noise magnetic field H is oriented from the negative side of the Y axis toward the positive side of the Y axis (oriented from the front side of the page toward the rear side of the page) flows. More specifically, Loop₁ is a path which connects the conductor wire 3, the capacitor 4, the case connection portion 5, the case 1, and the conductor wire 3, as shown by a broken line of FIG. 2A. Loop: is a path which connects the conductor wire 3, the capacitor 4, the case connection portion 5, the wall 6, the case 1, and the conductor wire 3, as shown by a broken line of FIG. 2B.

The noise magnetic field H varies with time. Therefore, when the noise magnetic field H interlinks with Loop₁ shown in FIG. 2A, an induced current I₁ is generated in Loop₁ and an induced voltage V₁ is generated between the case 1 and the terminal 2, which is an end of Loop₁, according to the law of electromagnetic induction. The electromagnetic noise caused by the induced voltage V₁ leaks out of the electrical and electronic apparatus from the terminal 2.

When the noise magnetic field H interlinks with Loop₂ shown in FIG. 2B, an induced current I₂ is generated in Loop₂ and an induced voltage V₂ is generated between the case 1 and the terminal 2, which is an end of Loop₂, according to the law of electromagnetic induction.

Assuming that a uniform magnetic field interlinks with the whole of Loop, each of the following quantities: the induced current and the induced voltage is proportional to the area of the magnetic field interlinking (referred to as the “interlinkage area” hereinafter). The interlinkage area is equal to the area of Loop.

Because the area of Loop: is smaller than the area of Loop₁, the interlinkage area in the case where the wall 6 is disposed in the electrical and electronic apparatus is smaller than the interlinkage area in the case where the wall 6 is not disposed in the electrical and electronic apparatus. Therefore, the induced current I₂ generated in Loop₂ is smaller than the induced current I₁ generated in Loop₁, as shown in the following equation (1), and the induced voltage V₂ generated at the end of Loop₂ is smaller than the induced voltage V₁ generated at the end of Loop₁, as shown in the following equation (2).

$${I}_{1} > {I}_{2} \qquad ( 1 )$$

$${V}_{1} > {V}_{2} \qquad ( 2 )$$

Further, when the noise magnetic field H varying with time strikes a surface portion of a conductor, an eddy current is generated inside the conductor. The generation of an eddy current inside the conductor causes a phenomenon in which a part of the magnetic energy is lost as heat. As shown in FIG. 2B, in the case where the wall 6 is disposed in the electrical and electronic apparatus, the energy of the noise magnetic field H decreases because the noise magnetic field H strikes a surface portion of the wall 6 and hence a part of the energy of the noise magnetic field H is lost in the wall 6.

Therefore, in the case where the wall 6 is disposed in the electrical and electronic apparatus, the energy of the noise magnetic field H is reduced to be less than that in the case where the wall 6 is not disposed in the electrical and electronic apparatus. Therefore, the induced current I₂ in the case where the wall 6 is disposed in the electrical and electronic apparatus is smaller than the induced current I₁ in the case where the wall 6 is not disposed in the electrical and electronic apparatus. Further, the induced voltage V₂ in the case where the wall 6 is disposed in the electrical and electronic apparatus is smaller than the induced voltage V₁ in the case where the wall 6 is not disposed in the electrical and electronic apparatus.

Therefore, the wall 6 disposed in the electrical and electronic apparatus reduces the leakage of the electromagnetic noise caused by the induced voltage V to be less than that in the case where the wall 6 is not disposed in the electrical and electronic apparatus.

A configuration of providing a shielding case having a size which makes it possible to enclose the whole of the filter circuit, instead of providing the electrical and electronic apparatus with the wall 6, also provides an advantageous effect of reducing the leakage of the electromagnetic noise. However, in order for the electrical and electronic apparatus to include such a shielding case, space (referred to as the “case placement space”) larger than the whole of the filter circuit needs to be provided as the placement space of the filter circuit.

In the electrical and electronic apparatus shown in FIGS. 1A and 1B, the wall 6 is placed in such a way that the side (the upper side in FIG. 1A) which is included in the four sides in the Z-X plane which the wall 6 has, and which is opposite to the side connected to the case 1 (the lower side in FIG. 1A) extends along the conductor wire 3.

Therefore, the placement space of the wall 6 is a partial region of the filter circuit, and is smaller than the case placement space.

In above-mentioned Embodiment 1, the electrical and electronic apparatus is configured in such a way as to include: the case 1 which is a conductor; the terminal 2 mounted to the case 1; the conductor wire 3 whose one end is connected to the terminal 2 and whose other end is connected to a circuit accommodated in the case 1; the capacitor 4 whose one end is connected to the conductor wire 3; the case connection portion 5 whose one end is connected to the other end of the capacitor 4 and whose other end is connected to the case 1; and the wall 6 whose peripheral part is in the space enclosed by the case 1, the conductor wire 3, and the case connection portion 5, and is connected to the case 1 in the state in which the wall is not in contact with the conductor wire 3. Therefore, the electrical and electronic apparatus can reduce the electromagnetic noise leaked out from the terminal 2 without having to dispose a shielding case having a size which makes it possible to enclose the whole of the filter circuit.

In the electrical and electronic apparatus shown in FIGS. 1A and 1B, the configuration in which the positive side terminal of a DC power supply disposed outside is connected, via a cable or the like, to the conductor included in the terminal 2, the negative side terminal of the DC power supply is connected, via a cable or the like, to the case 1, and power is supplied from the DC power supply to the electrical and electronic apparatus is shown. However, this is only an example, and the electrical and electronic apparatus may be configured in such a way as to supply power to an external device or to transmit and receive power to and from an external device.

In the electrical and electronic apparatus shown in FIGS. 1A and 1B, the configuration in which the positive side terminal of a DC power supply disposed outside is connected, via a cable or the like, to the conductor included in the terminal 2, and the negative side terminal of the DC power supply is connected, via a cable or the like, to the case 1 is shown. However, this is only an example, and two electrical and electronic apparatuses shown in FIGS. 1A and 1B may be arranged, the conductor included in the terminal 2 of one of the two electrical and electronic apparatuses may be connected, via a cable or the like, to the positive side terminal of a DC power supply disposed outside, and the conductor included in the terminal 2 of the other one of the two electrical and electronic apparatuses may be connected, via a cable or the like, to the negative side terminal of the DC power supply disposed outside.

Instead, the conductor included in the terminal 2 of one of the two electrical and electronic apparatuses may be connected, via a cable or the like, to the L phase of an alternating current power supply disposed outside, and the conductor included in the terminal 2 of the other one of the two electrical and electronic apparatuses is connected, via a cable or the like, to the N phase of the alternating current power supply disposed outside.

Instead, three electrical and electronic apparatuses shown in FIGS. 1A and 1B may be arranged, and the conductor included in the terminal 2 of each of the three electrical and electronic apparatuses may be connected, via a cable or the like, to each phase of a three-phase alternating current power supply disposed outside.

In the electrical and electronic apparatus shown in FIGS. 1A and 1B, the configuration in which the positive side terminal of a DC power supply disposed outside is connected, via a cable or the like, to the conductor included in the terminal 2, the negative side terminal of the DC power supply is connected, via a cable or the like, to the case 1, and power is supplied from the DC power supply to the electrical and electronic apparatus is shown. However, this is only an example, and the electrical and electronic apparatus may receive a signal transmitted from an external device or transmit a signal to an external device. Instead, the electrical and electronic apparatus may transmit and receive both power and a signal.

In the electrical and electronic apparatus shown in FIGS. 1A and 1B, the conductor wire 3 is a conductor such as a metal. However, this is only an example, and the conductor wire 3 may be a conducting wire with covering or a bus bar, for example. Instead of transmitting power, the conductor wire 3 may transmit a signal or a signal superimposed onto power,

In the electrical and electronic apparatus shown in FIGS. 1A and 1B, the first terminal of the capacitor 4 is connected to the conductor wire 3, and the second terminal of the capacitor 4 is connected to the one end of the case connection portion 5. However, this is only an example, and the first terminal of the capacitor 4 is connected to the conductor wire 3 and the second terminal of the capacitor 4 may be connected, not via the case connection portion 5, to the case 1.

Further, the capacitor 4 is a two-terminal capacitor part with a lead wire. However, this is only an example, and the capacitor 4 may be a surface mount type capacitor part.

In the electrical and electronic apparatus shown in FIGS. 1A and 1B, the case connection portion 5 is a pillar-shaped structure. The case connection portion 5 should just be able to electrically connect between the case 1 and the capacitor 4, and the structure can have any kind of shape. Therefore, the case connection portion 5 may be a prismatic structure or a cylindrical structure, for example.

In the electrical and electronic apparatus shown in FIGS. 1A and 1B, the wall 6 is placed in such a way that the distance D between the conductor wire 3 and the wall 6 is longer than the insulation distance. However, this is only an example, and the wall 6 may be placed in such a way that the distance D between the conductor wire 3 and the wall 6 is shorter than the insulation distance as long as the conductor wire 3 and the wall 6 are prevented from being in electrical contact with each other using an insulator or the like.

In the electrical and electronic apparatus shown in FIGS. 1A and 1B, the wall 6 is placed in such a way that a side on a left-hand side in FIG. 1A, out of the four sides in the Z-X plane which the wall 6 has, is connected to the case 1, and a side on a right-hand side in FIG. 1A, out of the four sides, is connected to the case connection portion 5. However, this is only an example, and the wall 6 may be placed in such a way that the side on the left-hand side in FIG. 1A is not electrically connected to the case 1, and the side on the right-hand side in FIG. 1A is not electrically connected to the case connection portion 5.

In the electrical and electronic apparatus shown in FIGS. 1A and 1B, the case 1 and the case connection portion 5 are separate structures. However, this is only an example, and the case 1 may be a structure integral with the case connection portion 5.

In the electrical and electronic apparatus shown in FIGS. 1A and 1B, the thickness in a direction parallel to the Y axis of the wall 6 is thicker than that in a direction parallel to the Y axis of the conductor wire 3. However, this is only an example, and the thickness in a direction parallel to the Y axis of the wall 6 may be the same as that in a direction parallel to the Y axis of the conductor wire 3 or thinner than that in a direction parallel to the Y axis of the conductor wire 3. Instead, the thickness in a direction parallel to the Y axis of the wall 6 may vary along a direction parallel to the X axis.

In the electrical and electronic apparatus shown in FIGS. 1A and 1B, the Y-Z cross section shape of the wall 6 is a rectangle. However, the Y-Z cross section shape of the wall 6 is not limited to a rectangle, and may be a triangle, a rhombus, or a hexagon, for example.

### Embodiment 2

In Embodiment 2, an electrical and electronic apparatus in which a coil 7 is inserted in series at a point in a conductor wire 3 will be explained.

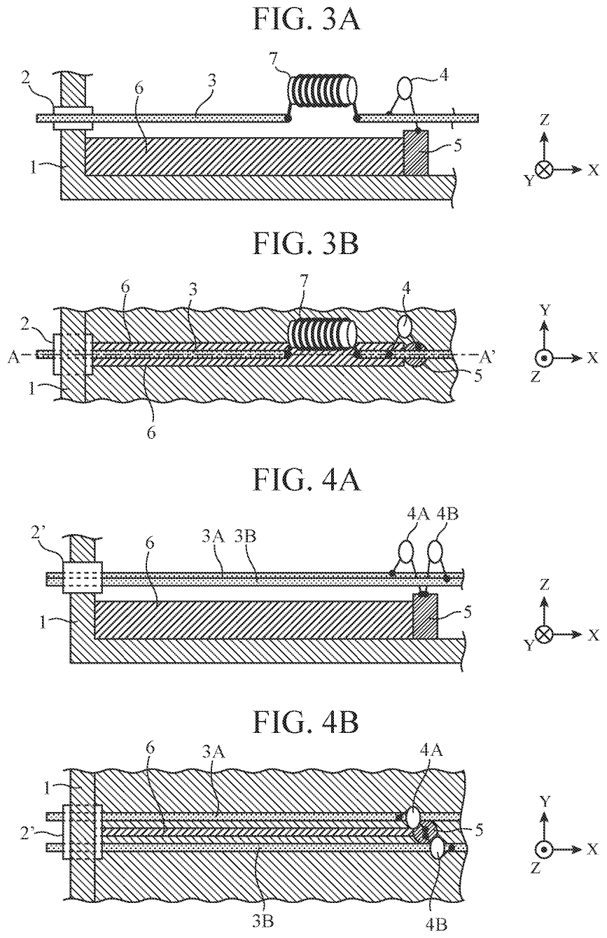

FIGS. 3A and 3B each is a configuration diagram showing a power supply terminal portion of the electrical and electronic apparatus according to Embodiment 2. In FIGS. 3A and 3B, because the same reference signs as those shown in FIG. 1A or 1B denote the same components or like components, an explanation of the components will be omitted hereinafter.

FIG. 3A is an explanatory drawing when a cross section A-A′ of the electrical and electronic apparatus shown in FIGS. 3A and 3B is viewed from a Y direction.

FIG. 3B is an explanatory drawing when the inside of a case 1 of the electrical and electronic apparatus is viewed from a Z direction.

The electrical and electronic apparatus shown in FIGS. 3A and 3B includes a filter circuit and an internal circuit. The filter circuit includes the case 1, a terminal 2, the conductor wire 3, a capacitor 4, a case connection portion 5, a wall 6, and the coil 7.

The coil 7 is a two-terminal part having a structure in which a conducting wire is coiled around a core which is a magnetic body.

The coil 7 is connected in series to the conductor wire 3 at a point, in the conductor wire 3, between the terminal 2 and the capacitor 4.

Next, the operation of the electrical and electronic apparatus shown in FIGS. 3A and 3B will be explained. Because the electrical and electronic apparatus is the same as the electrical and electronic apparatus shown in FIGS. 1A and 1B, except for the coil 7, only the operation of the coil 7 will be explained hereinafter.

The coil 7 is connected in series to the conductor wire 3 at a point, in the conductor wire 3, between the terminal 2 and the capacitor 4. Therefore, the coil 7 is contained in Loop: which is the path of an induced current I₂ generated when a noise magnetic field H interlinks.

Because the coil 7 is a high impedance part, the coil 7 acts in such a way that it is hard for the induced current I₂ to flow through the conductor wire 3. Therefore, the coil 7 acts in such a way as to make the induced voltage V₂ become small.

In above-mentioned Embodiment 2, the electrical and electronic apparatus shown in FIGS. 3A and 3B is configured in such a way that the coil 7 is inserted in series at a point in the conductor wire 3. Therefore, the electrical and electronic apparatus shown in FIGS. 3A and 3B can further reduce electromagnetic noise leaked out from the terminal 2 to be less than that reduced by the electrical and electronic apparatus shown in FIGS. 1A and 1B.

In the electrical and electronic apparatus shown in FIGS. 3A and 3B, the coil 7 has the structure in which a conducting wire is coiled around a core which is a magnetic body. However, this is only an example, and the coil 7 may have a structure in which a conducting wire is coiled around a toroidal core having a doughnut shape, for example. Further, the coil 7 may be an air-core coil in which a core which is a magnetic body is not used, for example.

In the electrical and electronic apparatus shown in FIGS. 3A and 3B, the coil 7 is inserted in series at a point in the conductor wire 3. However, a part inserted in series with the conductor wire 3 should just increase the impedance, and the electrical and electronic apparatus is not limited to the one in which the coil 7 is inserted in series at a point in the conductor wire 3. Therefore, a magnetic body such as a ferrite core may be inserted in series at a point in the conductor wire 3, for example.

### Embodiment 3

In Embodiment 3, an electrical and electronic apparatus which includes multiple conductor wire 3A and 3B as a conductor wire 3, and includes multiple capacitors 4A and 4B as a capacitor 4 will be explained.

FIGS. 4A and 4B each is a configuration diagram showing a power supply terminal portion of the electrical and electronic apparatus according to Embodiment 3. In FIGS. 4A and 4B, because the same reference signs as those shown in FIG. 1A or 1B denote the same components or like components, an explanation of the components will be omitted hereinafter.

FIG. 4A is an explanatory drawing when a cross section A-A′ of the electrical and electronic apparatus shown in FIGS. 4A and 4B is viewed from a Y direction.

FIG. 4B is an explanatory drawing when the inside of a case 1 of the electrical and electronic apparatus is viewed from a Z direction.

The electrical and electronic apparatus shown in FIGS. 4A and 4B includes a filter circuit and an internal circuit. The filter circuit includes the case 1, a terminal 2′, and the conductor wires 3A and 3B, the capacitors 4A and 4B, a case connection portion 5, and a wall 6.

The terminal 2′ is mounted to the case 1 in order to electrically connect each of the conductor wires 3A and 3B and an external device or the like outside the electrical and electronic apparatus.

The terminal 2′ is a connector including two conductors such as metals, and an insulator such as resin. One of the conductors included in the terminal 2′ is connected to the conductor wire 3A, and the other one of the conductors included in the terminal 2′ is connected to the conductor wire 3B. The insulator included in the terminal 2′ is mounted to the case 1 in such a way that the two conductors are not in contact with each other and each of the conductors is not in contact with the case 1.

One end of the conductor wire 3A is connected to the one of the conductors included in the terminal 2′, and the other end of the conductor wire 3A is connected to the internal circuit.

One end of the conductor wire 3B is connected to the other one of the conductors included in the terminal 2′, and the other end of the conductor wire 3B is connected to the internal circuit.

Each of the conductor wires 3A and 3B is a conductor such as a metal. The conductor wires 3A and 3B are arranged in parallel in a state in which they are not in contact with each other.

In the electrical and electronic apparatus shown in FIGS. 4A and 4B, the conductor wires 3A and 3B are arranged in parallel. However, this is only an example, and the conductor wire 3A and the conductor wire 3B may be arranged in non-parallel.

In FIG. 4A, the conductor wires 3A and 3B are spaced apart from each other with respect to a direction of a Z axis. In the figure, in order to facilitate the distinction between the conductor wire 3A and the conductor wire 3B, the conductor wires are shown to be spaced apart from each other with respect to a direction of the Z axis. Therefore, the conductor wires 3A and 3B do not need to be spaced apart from each other with respect to a direction of the Z axis.

Each of the capacitors 4A and 4B is a two-terminal capacitor part with a lead wire.

A first terminal which is one end of the capacitor 4A is connected to the conductor wire 3A. A second terminal which is the other end of the capacitor 4A is connected to one end of the case connection portion 5.

A first terminal which is one end of the capacitor 4B is connected to the conductor wire 3B. A second terminal which is the other end of the capacitor 4B is connected to the one end of the case connection portion 5.

The wall 6 is a surface-shaped structure which is constituted by a conductor such as a metal.

The wall 6 has a peripheral part which is in space formed by the case 1, the case connection portion 5, and the conductor wires 3A and 3B, and which is connected to the case 1 in a state in which the wall is not in contact with the conductor wire 3.

In the electrical and electronic apparatus shown in FIGS. 1A and 1B, a lower side in FIG. 4A of the wall 6, which is defined as the peripheral part, is connected to the case 1.

In the electrical and electronic apparatus shown in FIGS. 4A and 4B, the wall 6 is placed in such a way that an upper side in FIG. 4A of the wall 6 extends along the conductor wires 3A and 3B. Further, each of the following distances: the distance between the conductor wire 3A and the upper side in FIG. 4A, and the distance between the conductor wire 3B and the upper side in FIG. 4A is longer than an insulation distance decided by a safety standard or the like, in order to prevent electrical shorts or electric discharges in space.

Next, the operation of the electrical and electronic apparatus shown in FIGS. 4A and 4B will be explained.

Hereinafter, for sake of in the convenience explanation, it is assumed that a positive side terminal of a DC power supply (not illustrated) outside the electrical and electronic apparatus is connected, via a cable or the like, to the one of the conductors included in the terminal 2′, and a negative side terminal of the DC power supply is connected, via a cable or the like, to the other one of the conductors included in the terminal 2′. Therefore, the conductor wire 3A is electrically connected to the positive side terminal of the DC power supply, and the conductor wire 3B is electrically connected to the negative side terminal of the DC power supply.

Power supplied from the DC power supply is supplied, via the conductors included in the terminal 2′ and the conductor wires 3A and 3B, to the internal circuit. When the internal circuit operates, noise may be generated from the internal circuit.

Noise generated from the internal circuit is superimposed, as a noise voltage or a noise current, onto each of the conductor wires 3A and 3B.

The capacitor 4A acts in such a way that the noise current superimposed onto the conductor wire 3A easily flows through the case 1. Further, the capacitor 4B acts in such a way that the noise current superimposed onto the conductor wire 3B easily flows through the case 1.

Therefore, because the electrical and electronic apparatus includes the capacitor 4A, the electric potential difference between the case 1 and the conductor wire 3A becomes small. Further, because the electrical and electronic apparatus includes the capacitor 4B, the electric potential difference between the case 1 and the conductor wire 3B becomes small.

Each of the electric potential differences: the electric potential difference between the case 1 and the conductor wire 3A, and the electric potential difference between the case 1 and the conductor wire 3B corresponds to the noise voltage generated between the case 1 and the terminal 2′. As a result, the amount of leakage of electromagnetic noise from the terminal 2 to the outside, the electromagnetic noise being caused by the noise voltage, decreases.

In the electrical and electronic apparatus shown in FIGS. 4A and 4B, the conductor wires 3A and 3B are arranged in parallel in the state in which they are not in contact with each other. Therefore, when a noise magnetic field H interlinks, as shown in FIG. 2B, induced currents I₂ being substantially in phase and having substantially the same amplitude is generated in the conductor wires 3A and 3B. Components in phase and having the same amplitude can be decomposed as a common mode component and components in opposite phase and having the same amplitude can be decomposed as a normal mode component, between two or more conductor lines. Therefore, the induced currents I₂ can be handled as a common mode current, and induced voltages Ve caused by the induced current I₂ can be handled as a common mode voltage. When only the common mode component is assumed, it becomes possible to handle the conductor wires 3A and 3B as a single conductor wire. More specifically, the electrical and electronic apparatus shown in FIGS. 4A and 4B which has the conductor wires 3A and 3B can be handled in the same way that the electrical and electronic apparatus shown in FIGS. 1A and 1B which has the single conductor wire 3 is handled.

Therefore, in the electrical and electronic apparatus shown in FIGS. 4A and 4B, the provision of the wall 6 reduces the interlinkage area of the noise magnetic field H to be smaller than that in the case where the wall 6 is not provided, like in the case of the electrical and electronic apparatus shown in FIGS. 1A and 1B. As a result, the provision of the wall 6 reduces the induced voltages V₂ to be smaller than those in the case where the wall 6 is not provided.

Further, in the electrical and electronic apparatus shown in FIGS. 4A and 4B, the provision of the wall 6 reduces the energy of the noise magnetic field H to smaller than that in the case where the wall 6 is not provided, like in the case of the electrical and electronic apparatus shown in FIGS. 1A and 1B. As a result, the provision of the wall 6 reduces the induced voltages V₂ to be smaller than those in the case where the wall 6 is not provided.

Therefore, in the electrical and electronic apparatus shown in FIGS. 4A and 4B, the provision of the wall 6 in the electrical and electronic apparatus reduces the noise voltage in the common mode to be smaller than that in the case where the wall 6 is not provided.

In above-mentioned Embodiment 3, the electrical and electronic apparatus is configured in such a way as to include the multiple conductor wires 3A and 3B as the conductor wire 3, the multiple conductor wires 3A and 3B being arranged in parallel in the state in which they are not in contact with each other, and the multiple capacitors 4A and 4B as the capacitor 4, and in such a way that the one end of each of the capacitors 4A and 4B is connected to each of the conductor wires 3A and 3B, and the other end of each of the capacitors 4A and 4B is connected to the case connection portion 5. Therefore, the electrical and electronic apparatus can reduce the electromagnetic noise in the common mode leaked out from the terminal 2′ without having to dispose a shielding case having a size which makes it possible to enclose the whole of the filter circuit.

In the electrical and electronic apparatus shown in FIGS. 4A and 4B, the configuration in which the positive side terminal of a DC power supply present outside is connected, via a cable or the like, to one of the conductors included in the terminal 2′, the negative side terminal of the DC power supply is connected, via a cable or the like, to the other one of the conductors included in the terminal 2′, and power is supplied from the DC power supply to the electrical and electronic apparatus is shown. However, this is only an example, and the electrical and electronic apparatus may be configured in such a way as to supply power to an external device or to transmit and receive power to and from an external device.

In the electrical and electronic apparatus shown in FIGS. 4A and 4B, the conductor wire 3A is electrically connected to the positive side terminal of the DC power supply, and the conductor wire 3B is electrically connected to the negative side terminal of the DC power supply. However, this is only an example, and the conductor wire 3A may be electrically connected to the L phase of an alternating current power supply present outside, and the conductor wire 3B may be electrically connected to the N phase of the alternating current power supply.

In the electrical and electronic apparatus shown in FIGS. 4A and 4B, the terminal 2′ contains the two conductor wires 3A and 3B. The electrical and electronic apparatus may include, instead of the terminal 2′, two terminals: a terminal containing the conductor wire 3A, and a terminal containing the conductor wire 3B.

The electrical and electronic apparatus shown in FIGS. 4A and 4B includes the two conductor wires 3A and 3B as the conductor wire 3. However, this is only an example, and the electrical and electronic apparatus may include three or more conductor wires 3 and a terminal 2′ containing the three or more conductor wires 3. In the case where the electrical and electronic apparatus includes three conductor wires 3, for example, each of the conductor wires 3 may be electrically connected to each phase of a three-phase alternating current power supply present outside.

In the electrical and electronic apparatus shown in FIGS. 4A and 4B, the conductor wires 3A and 3B are conductors such as metals. However, this is only an example, and the conductor wires 3A and 3B may be conducting wires with covering or bus bars, for example. Instead of transmitting power, the conductor wires 3A and 3B may transmit a signal or a signal superimposed onto power.

In the electrical and electronic apparatus shown in FIGS. 4A and 4B, the first terminal of the capacitor 4A is connected to the conductor wire 3A, and the second terminal of the capacitor 4A is connected to the one end of the case connection portion 5. Further, the first terminal of the capacitor 4B is connected to the conductor wire 3B, and the second terminal of the capacitor 4B is connected to the one end of the case connection portion 5. However, this is only an example, and the first terminal of the capacitor 4A is connected to the conductor wire 3A and the second terminal of the capacitor 4A may be connected, not via the case connection portion 5, to the case 1. Further, the first terminal of the capacitor 4B is connected to the conductor wire 3B, and the second terminal of the capacitor 4B may be connected, not via the case connection portion 5, to the case 1.

Further, the capacitors 4A and 4B are two-terminal capacitor parts with a lead wire. However, this is only an example, and the capacitors 4A and 4B may be surface mount type capacitor parts.

In the electrical and electronic apparatus shown in FIGS. 4A and 4B, the case connection portion 5 is a pillar-shaped structure. The case connection portion 5 should just be able to electrically connect between the case 1 and the capacitor 4A and between the case 1 and the capacitor 4B, and the structure can have any kind of shape. Therefore, the case connection portion 5 may be a prismatic structure or a cylindrical structure, for example.

The electrical and electronic apparatus shown in FIGS. 4A and 4B includes the single case connection portion 5. However, this is only an example, and the electrical and electronic apparatus may include two case connection portions 5. For example, the electrical and electronic apparatus may include a case connection portion 5 which electrically connects between the case 1 and the capacitor 4A, and a case connection portion 5 which electrically connects between the case 1 and the capacitor 4B. In this case, the wall 6 should just be placed between one of the case connection portions 5 and the terminal 2′.

In the electrical and electronic apparatus shown in FIGS. 4A and 4B, the wall 6 is placed in such a way that each of the following distances: the distance between the conductor wire 3A and the wall 6, and the distance between the conductor wire 3B and the wall 6 is longer than the insulation distance. However, this is only an example, and the wall 6 may be placed in such a way that each of the following distances: the distance between the conductor wire 3A and the wall 6, and the distance between the conductor wire 3B and the wall 6 is shorter than the insulation distance as long as each of the conductor wires 3A and 3B and the wall 6 are prevented from being in electrical contact with each other using an insulator or the like.

In the electrical and electronic apparatus shown in FIGS. 4A and 4B, it is assumed that the wall 6 is placed, between the terminal 2′ and the case connection portion 5, at equal distances from the conductor wire 3A and from the conductor wire 3B. However, this is only an example, and the wall 6 may be placed, between the terminal 2′ and the case connection portion 5, at different distances from the conductor wire 3A and from the conductor wire 3B.

In the case where the electrical and electronic apparatus includes three conductor wires 3, the wall 6 should just be placed inside two conductor wires 3 arranged on both sides, out of the three conductor wires 3.

For example, assuming that the three Y coordinates at which the three conductor wires 3 whose longitudinal directions are parallel to an X axis are respectively placed are Y₁, Y₂, and Y₃, and Y₁>Y>Y₃ holds, the Y coordinate at which the wall 6 is placed should just be greater than or equal to Y₃ and less than or equal to Y₁. Y₁>=Y coordinate at which the wall 6 is placed>=Y₃ holds.

In the electrical and electronic apparatus shown in FIGS. 4A and 4B, the wall 6 is placed in such a way that a side on a left-hand side in FIG. 4A, out of four sides in a Z-X plane which the wall 6 has, is connected to the case 1, and a side on a right-hand side in FIG. 4A, out of the four sides, is connected to the case connection portion 5. However, this is only an example, and the wall 6 may be placed in such a way that the side on the left-hand side in FIG. 4A is not electrically connected to the case 1, and the side on the right-hand side in FIG. 4A is not electrically connected to the case connection portion 5.

In the electrical and electronic apparatus shown in FIGS. 4A and 4B, the case 1 and the case connection portion 5 are separate structures. However, this is only an example, and the case 1 may be a structure integral with the case connection portion 5.

In the electrical and electronic apparatus shown in FIGS. 4A and 4B, the Y-Z cross section shape of the wall 6 is a rectangle. However, the Y-Z cross section shape of the wall 6 is not limited to a rectangle, and may be a triangle, a rhombus, or a hexagon, for example.

### Embodiment 4

In Embodiment 4, an electrical and electronic apparatus in which a coil 8 is inserted in series at a point in conductor wires 3A and 3B will be explained.

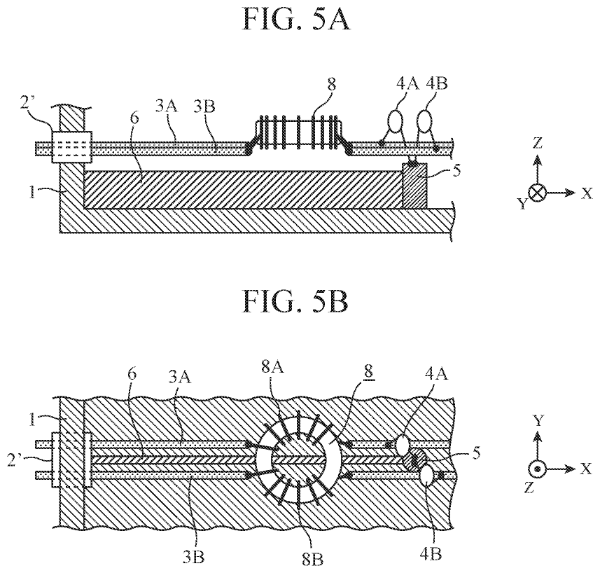

FIGS. 5A and 5B each is a configuration diagram showing a power supply terminal portion of the electrical and electronic apparatus according to Embodiment 4. In FIGS. 5A and 5B, because the same reference signs as those shown in FIGS. 1 and 4 denote the same components or like components, an explanation of the components will be omitted hereinafter.

FIG. 5A is an explanatory drawing when a cross section A-A′ of the electrical and electronic apparatus shown in FIGS. 5A and 5B is viewed from a Y direction.

FIG. 5B is an explanatory drawing when the inside of a case 1 of the electrical and electronic apparatus is viewed from a Z direction.

The electrical and electronic apparatus shown in FIGS. 5A and 5B includes a filter circuit and an internal circuit. The filter circuit includes the case 1, a terminal 2′, the conductor wires 3A and 3B, capacitors 4A and 4B, a case connection portion 5, a wall 6, and the coil 8.

The coil 8 is a four-terminal part having a structure in which two conducting wires are coiled around the core of a magnetic body.

More specifically, the coil 8 is a common mode choke coil having coils 8A and 8B.

The coil 8A is connected in series to the conductor wire 3A at a point, in the conductor wire 3A, between one of conductors included in the terminal 2′ and the capacitor 4A.

The coil 8B is connected in series to the conductor wire 3B at a point, in the conductor wire 3B, between the other one of the conductors included in the terminal 2′ and the capacitor 4B.

Next, the operation of the electrical and electronic apparatus shown in FIGS. 5A and 5B will be explained. Because the electrical and electronic apparatus is the same as the electrical and electronic apparatus shown in FIGS. 4A and 4B, except for the coil 8, only the operation of the coil 8 will be explained hereinafter.

The coil 8A is connected in series to the conductor wire 3A at a point, in the conductor wire 3A, between one of conductors included in the terminal 2′ and the capacitor 4A. Further, the coil 8B is connected in series to the conductor wire 3B at a point, in the conductor wire 3B, between the other one of the conductors included in the terminal 2′ and the capacitor 4B. Therefore, the coils 8A and 8B are contained in Loop: which is a path for an induced current I₂ generated when a noise magnetic field H interlinks.

Because each of the coils 8A and 8B is a high impedance part, each of the coils thus acts to make it difficult for the induced current I₂ to flow through each of the conductor wires 3A and 3B. Therefore, each of the coils 8A and 8B acts in such a way as to make an induced voltage V₂ become small.

In above-mentioned Embodiment 5, the electrical and electronic apparatus shown in FIGS. 5A and 5B is configured in such a way that the coil 8A is inserted in series at a point in the conductor wire 3A and the coil 8B is inserted in series at a point in the conductor wire 3B. Therefore, the electrical and electronic apparatus shown in FIGS. 5A and 5B can further reduce electromagnetic noise leaked out from the terminal 2 to smaller than that in the electrical and electronic apparatus shown in FIGS. 4A and 4B.

In the electrical and electronic apparatus shown in FIGS. 5A and 5B, the coil 8 has the structure in which two conducting wires are coiled around the core of a magnetic body. However, this is only an example, and the coil 8 may be a common mode choke coil having another shape, for example. Instead, the coil 8 may be an air-core coil in which the core of a magnetic body is not used, for example.

In the electrical and electronic apparatus shown in FIGS. 5A and 5B, the coil 8A is inserted in series at a point in the conductor wire 3A, and the coil 8B is inserted in series at a point in the conductor wire 3B. However, the part inserted in series in the conductor wire 3A should just increase the impedance, and the electrical and electronic apparatus is not limited to the one in which the coil 8A is inserted in series at a point in the conductor wire 3A. Further, the part inserted in series in the conductor wire 3B should just increase the impedance, and the electrical and electronic apparatus is not limited to the one in which the coil 8B is inserted in series at a point in the conductor wire 3B. Therefore, for example, a magnetic body, such as a ferrite core, may be inserted in series at a point in each of the conductor wires 3A and 3B.

In the case where the electrical and electronic apparatus includes three or more conductor wires 3, a common mode choke coil having terminals the number of which is equal to the number of conductor wires 3 should just be used as the coil 8.

### Embodiment 5

In Embodiment 5, an electrical and electronic apparatus which includes a capacitor 9 will be explained.

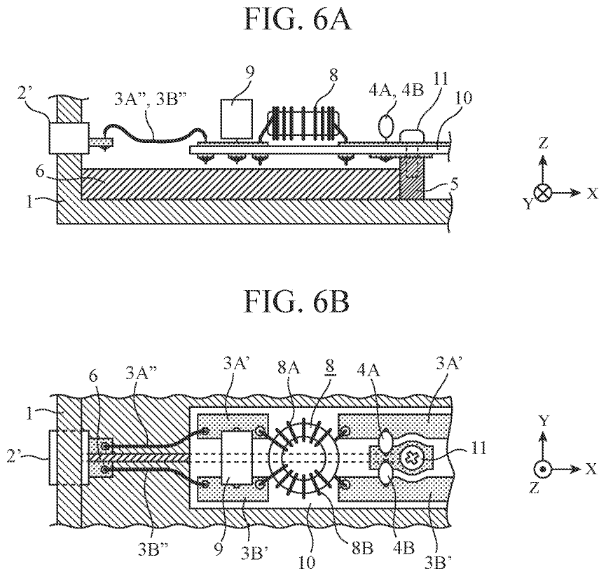

FIGS. 6A and 6B each is a configuration diagram showing a power supply terminal portion of the electrical and electronic apparatus according to Embodiment 5. In FIGS. 6A and 6B, because the same reference signs as those shown in FIGS. 1, 4, and 5 denote the same components or like components, an explanation of the components will be omitted hereinafter.

FIG. 6A is an explanatory drawing when a cross section A-A′ of the electrical and electronic apparatus shown in FIGS. 6A and 6B is viewed from a Y direction.

FIG. 6B is an explanatory drawing when the inside of a case 1 of the electrical and electronic apparatus is viewed from a Z direction.

The electrical and electronic apparatus shown in FIGS. 6A and 6B includes a filter circuit and an internal circuit. The filter circuit includes the case 1, a terminal 2′, conductor wires 3A and 3B, capacitors 4A and 4B, a case connection portion 5, a wall 6, a coil 8, the capacitor 9, a printed circuit board 10, and a screw 11.

In the electrical and electronic apparatus shown in FIGS. 6A and 6B, the conductor wire 3A includes a wiring pattern 3A′ and a lead wire 3A″. Further, the conductor wire 3B includes a wiring pattern 3B′ and a lead wire 3B″.

The capacitor 9 is a so-called X capacitor.

The capacitor 9 is a two-terminal capacitor part. One end of the capacitor 9 is connected to the wiring pattern 3A′. The other end of the capacitor 9 is connected to the wiring pattern 3B′.

The capacitor 9 is placed in order to suppress a magnetic field coupling between Loop: containing the capacitor 4A and Loop: containing the capacitor 4B, thereby reducing the leakage of electromagnetic noise.

On the printed circuit board 10, a part of the conductor wire 3A is printed as the wiring pattern 3A′, and a part of the conductor wire 3B is printed as the wiring pattern 3B′.

In the electrical and electronic apparatus shown in FIGS. 6A and 6B, one end of the lead wire 3A″ which is a part of the conductor wire 3A is connected to one of conductors included in the terminal 2′, and the other end of the lead wire 3A″ is connected to one end of the wiring pattern 3A′.

Further, one end of the lead wire 3B″ which is a part of the conductor wire 3B is connected to the other one of the conductors included in the terminal 2′, and the other end of the lead wire 3B″ is connected to one end of the wiring pattern 3B′.

The screw 11 is disposed in order to fix the case connection portion 5 to the printed circuit board 10 and to electrically connect the wiring patterns 3A′ and 3B′ printed on the printed circuit board 10 to the case connection portion 5.

Next, the operation of the electrical and electronic apparatus shown in FIGS. 6A and 6B will be explained.

The electrical and electronic apparatus shown in FIGS. 6A and 6B includes the capacitor 9.

The capacitor 9 can suppress the magnetic field coupling between Loop: containing the capacitor 4A and Loop-containing the capacitor 4B, thereby being able to reduce the leakage of the electromagnetic noise. Therefore, the electrical and electronic apparatus shown in FIGS. 6A and 6B can further reduce the leakage of the electromagnetic noise to smaller than that from the electrical and electronic apparatus shown in FIGS. 5A and 5B.

In above-mentioned Embodiment 5, the two conductor wires 3A and 3B are included as the conductor wire 3, and the two conductor wires 3A and 3B are arranged in parallel in a state in which they are not in contact with each other. The electrical and electronic apparatus shown in FIGS. 6A and 6B is configured in such a way as to include the capacitor 9 whose one end is connected to the conductor wire 3A which is one of the two conductor wires 3A and 3B, and whose other end is connected to the conductor wire 3B which is the other one of the two conductor wires 3A and 3B. Therefore, the electrical and electronic apparatus shown in FIGS. 6A and 6B can further reduce the leakage of the electromagnetic noise to smaller than that from the electrical and electronic apparatus shown in FIGS. 5A and 5B.

In the electrical and electronic apparatus shown in FIGS. 6A and 6B, the capacitor 9 is connected between the wiring pattern 3A′ on the terminal 2′ side of the coil 8A and the wiring pattern 3B′ on the terminal 2′ side of the coil 8B. However, this is only an example, and the capacitor 9 may be connected between the wiring pattern 3A′ existing between the coil 8A and the capacitor 4A, and the wiring pattern 3B′ existing between the coil 8B and the capacitor 4B.

Instead, the capacitor 9 may be connected between the wiring pattern 3A′ on the internal circuit side of the capacitor 4A and the wiring pattern 3B′ on the internal circuit side of the capacitor 4B.

Instead, the capacitor 9 may be connected between the lead wire 3A″ and the lead wire 3B″.

In the electrical and electronic apparatus shown in FIGS. 6A and 6B, the screw 11 fixes the case connection portion 5 to the printed circuit board 10. However, what is necessary is just to be able to fix the case connection portion 5 to the printed circuit board 10, and the electrical and electronic apparatus does not have to use the screw 11. Therefore, the electrical and electronic apparatus may be configured in such a way that the case connection portion 5 is fixed to the printed circuit board 10 using crimping, for example, instead of using the screw 11. Instead, the electrical and electronic apparatus may be configured in such a way that the case connection portion 5 is fixed to the printed circuit board 10 using caulking, or the case connection portion 5 is pressed against the printed circuit board 10 by a spring.

In the electrical and electronic apparatus shown in FIGS. 6A and 6B, the wiring patterns 3A′ and 3B′ are printed on one side of the printed circuit board 10. The printed circuit board 10 may be a single-sided board, a double-sided board, or a multilayer board having three or more layers.

Further, the printed circuit board 10 should just make it possible to physically support electronic parts including the capacitor 9, and to make an electrical connection to the terminal 2′, and it does not matter what type of conductive material the wiring patterns 3A′ and 3B′ are made from and what type of material an insulator is made from.

The printed circuit board 10 is fixed to the case connection portion 5 by the screw 11, so that the printed circuit board 10 is fixed to the case 1. However, this is only an example, and the printed circuit board 10 may be fixed directly to the case 1.

In the electrical and electronic apparatus shown in FIGS. 6A and 6B, one of the conductors included in the terminal 2′ is electrically connected, via the lead wire 3A″, to the wiring pattern 3A′, and the other one of the conductors included in the terminal 2′ is electrically connected, via the lead wire 3B″, to the wiring pattern 3B′. One of the conductors included in the terminal 2′ should just be electrically connected to the wiring pattern 3A′ and the other one of the conductors included in the terminal 2′ should just be electrically connected to the wiring pattern 3B′, and bus bars may be used instead of the lead wires 3A″ and 3B″, for example.

In the electrical and electronic apparatus shown in FIGS. 6A and 6B, the case 1 and the case connection portion 5 are separate structures. However, this is only an example, and the case 1 may be a structure integral with the case connection portion 5.

### Embodiment 6

In the electrical and electronic apparatus according to Embodiments 1 to 5, the wall 6 is a surface-shaped structure which is constituted by a conductor such as a metal. However, this is only an example, and the wall 6 may be a surface-shaped structure which is constituted by a magnetic body. A peripheral part of the wall 6 should just be mechanically connected to the case 1, while the peripheral part of the wall 6 is not electrically connected to the case 1.

In the case where the wall 6 is a non-conductive magnetic body such as ferrite, for example, the advantageous effect of reducing the interlinkage area, the advantageous effect being caused by the reduction of the Loop area, is not provided because the noise magnetic field H passes through the wall 6.

However, a phenomenon in which a part of the noise magnetic field H is lost as heat occurs when the noise magnetic field H passes through the wall 6. Therefore, the energy which the noise magnetic field H has decreases to be less than that in the case where the wall 6 is not included. The decrease in the energy which the noise magnetic field H has results in decrease in the induced current generated in Loop₂ and in the induced voltage generated at the terminal 2′.

Therefore, the electrical and electronic apparatus according to Embodiment 6 can reduce the electromagnetic noise leaked out from the terminal 2 without having to include a shielding case having a size which makes it possible to enclose the whole of a filter circuit, like the electrical and electronic apparatus according to Embodiments 1 to 5.

Further, the wall 6 has nonconductivity. Therefore, it is not necessary to take into consideration the insulation distance between the wall 6 and each of the conductor wires 3A and 3B. Therefore, the wall 6 can be placed close to the conductor wires 3A and 3B without using an insulator or the like.

It is to be understood that an arbitrary combination of two or more of the above-mentioned embodiments can be made, various changes can be made in an arbitrary component according to any one of the above-mentioned embodiments, or an arbitrary component according to any one of the above-mentioned embodiments can be omitted.

### INDUSTRIAL APPLICABILITY

The present disclosure is suitable for an electrical and electronic apparatus.

### REFERENCE SIGNS LIST

1 case, 2, 2′ terminal, 3, 3A, 3B conductor wire, 3A′, 3B′ wiring pattern, 3A″, 3B″ lead wire, 4, 4A, 4B capacitor, 5 case connection portion, 6 wall, 7 coil, 8, 8A, 8B coil, 9 capacitor, 10 printed circuit board, and 11 screw.

1. An electrical and electronic apparatus comprising:
a case which is a conductor;
a terminal mounted to the case;
at least one conductor wire whose one end is connected to the terminal and whose other end is connected to a circuit accommodated in the case;
at least one capacitor whose one end is connected to the at least one conductor wire;
a case connection portion whose one end is connected to another end of the at least one capacitor and whose other end is connected to the case; and
a wall whose peripheral part is connected to the case, the wall being positioned in space enclosed by the case, the at least one conductor wire, and the case connection portion, and being in a state in which the wall is not in contact with the at least one conductor wire, wherein the wall is placed in such a way that a side opposite to another side connected to the wall, out of sides which the case has, extends along the at least one conductor wire.

2. The electrical and electronic apparatus according to claim 1, wherein a coil is intermediately inserted to the at least one conductor wire in series.

3. The electrical and electronic apparatus according to claim 1, wherein the electrical and electronic apparatus includes, as the at least one conductor wire, a plurality of conductor wires, and the plurality of conductor wires is arranged in a state in which the conductor wires are not in contact with one another, and
the electrical and electronic apparatus includes, as the at least one capacitor, a plurality of capacitors, and ends of the capacitors are connected to the conductor wires, respectively, and other ends of the capacitors are connected to the case connection portion.

4. The electrical and electronic apparatus according to claim 3, wherein a coil is intermediately inserted to each of the conductor wires in series.

5. The electrical and electronic apparatus according to claim 1, wherein a distance between the at least one conductor wire and the wall is longer than an insulation distance.

6. The electrical and electronic apparatus according to claim 1, wherein the electrical and electronic apparatus includes, as the at least one conductor wire, two conductor wires and the two conductor wires are arranged in a state not to be in contact with each other, and the electrical and electronic apparatus includes another capacitor whose one end is connected to one of the two conductor wires and whose other end is connected to another one of the two conductor wires.

7. The electrical and electronic apparatus according to claim 1, wherein the wall is a conductor.

8. The electrical and electronic apparatus according to claim 1, wherein the wall is a magnetic body.
